(19) United States
(12) Patent Application Publication
(10) Pub. No.: US 2025/0113521 A1
(43) Pub. Date: Apr. 3, 2025

(54) DIRECT TRANSFER OF TRANSITION METAL DICHALCOGENIDE MONOLAYERS USING DIFFUSION BONDING LAYERS

(71) Applicant: Intel Corporation, Santa Clara, CA (US)

(72) Inventors: Andrey Vyatskikh, Hillsboro, OR (US); Paul B. Fischer, Portland, OR (US); Paul Killian Nordeen, Portland, OR (US); Uygar E. Avci, Portland, OR (US); Mahmut Sami Kavrik, Eugene, OR (US); Ande Kitamura, Portland, OR (US); Kirby Maxey, Hillsboro, OR (US); Carl Hugo Naylor, Portland, OR (US); Kevin P. O'Brien, Portland, OR (US)

(73) Assignee: Intel Corporation, Santa Clara, CA (US)

(21) Appl. No.: 18/478,626

(22) Filed: Sep. 29, 2023

(51) Int. Cl. H01L 29/775; H01L 21/762

(52) U.S. Cl. CPC H10D 30/43; H01L 21/76259

(57) ABSTRACT

A transition metal dichalcogenide (TMD) monolayer grown on a growth substrate is directly transferred to a target substrate. Eliminating the use of a carrier wafer in the TMD monolayer transfer process reduces the number of transfers endured by the TMD monolayer from two to one, which can result in less damage to the TMD monolayer. After a TMD monolayer is grown on a growth layer, a protective layer is formed on the TMD monolayer. The protective layer is bonded to the target substrate by a diffusion bonding layer. The direct transfer of TMD monolayers can be repeated to create a stack of TMD monolayers. A stack of TMD monolayers can be used in a field effect transistor, such as a nanoribbon field effect transistor.

### BACKGROUND

Transition metal dichalcogenides (TMD) monolayers are a candidate material for use in field effect transistors. One approach to integrating TMD monolayers into semiconductor device processing flows is to grow TMD monolayers on growth substrates and transfer the TMD monolayers to a target substrate on which field effect transistors utilizing TMD monolayers are to be fabricated.

### BRIEF DESCRIPTION OF THE DRAWINGS

FIGS. 1A-1E are cross-sectional views of a simplified example processing flow of transferring a transition metal dichalcogenide (TMD) monolayer from a growth substrate to a target substrate involving two transfers of the TMD monolayer.

FIGS. 2A-2E are cross-sectional views of a simplified example processing flow of directly transferring a first TMD monolayer from a growth substrate to a target substrate.

FIGS. 3A-3E are cross-sectional views of a simplified example processing flow of directly transferring a second transition metal dichalcogenide (TMD) monolayer from a growth substrate to the target substrate of FIGS. 2C-2E.

FIG. 4 illustrates an example structure comprising a TMD monolayer stack formed by direct transfer of TMD monolayers from growth substrates to a target substrate.

FIG. 5 is a cross-sectional view of an example integrated circuit die comprising two TMD monolayer stacks.

FIG. 6 is an example method of directly transferring a TMD monolayer from a growth substrate to a target substrate.

FIG. 7 is a top view of a wafer and dies that may be included in a microelectronic assembly, in accordance with any of the embodiments disclosed herein.

FIG. 8 is a cross-sectional side view of an integrated circuit device that may be included in a microelectronic assembly, in accordance with any of the embodiments disclosed herein.

FIGS. 9A-9D are perspective views of example planar, FinFET, gate-all-around, and stacked gate-all-around transistors.

FIGS. 10A and 10B are perspective and cross-sectional views of example forksheet gate-all-around transistors.

FIGS. 11A and 11B are perspective and cross-sectional views of an example complementary field-effect-transistor (CFET) architecture.

FIG. 12 is a cross-sectional side view of an integrated circuit device assembly that may include a microelectronic assembly, in accordance with any of the embodiments disclosed herein.

FIG. 13 is a block diagram of an example electrical device that may include a microelectronic assembly, in accordance with any of the embodiments disclosed herein.

### DETAILED DESCRIPTION

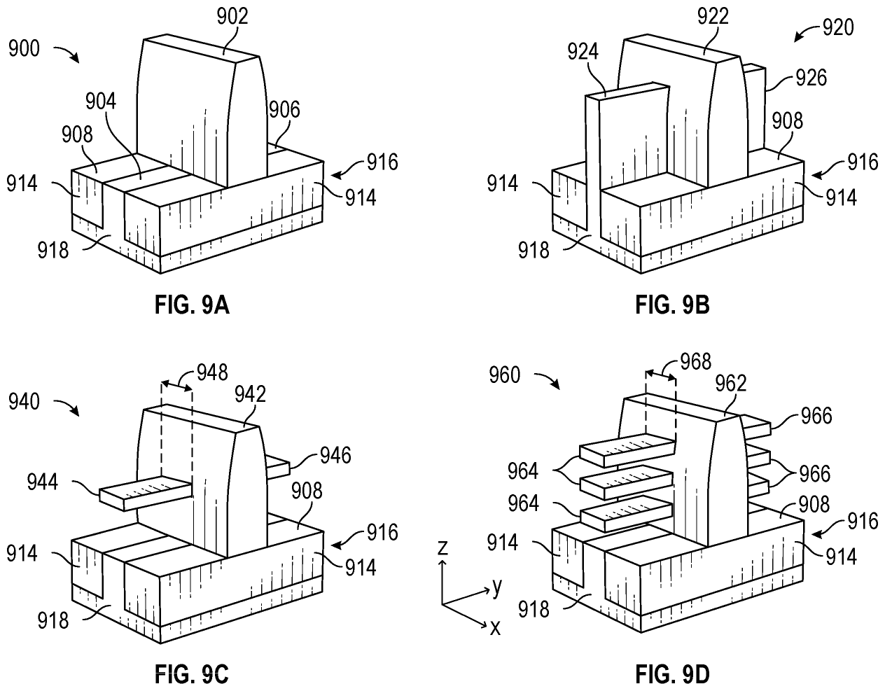

Transition metal dichalcogenides (TMD) monolayers are a candidate material for use in field effect transistors (FETs). For example, TMD monolayers are a candidate material for use as the channel region material in nanoribbon (nanosheet, nanowire) transistors of the type illustrated in FIG. 9D. One approach to integrating TMD monolayers into semiconductor device processing flows is to grow TMD monolayers on growth substrates and transfer the TMD monolayers to a target substrate on which FETs comprising TMD monolayers are to be formed. One advantage of growing TMD monolayers on a substrate that is different from a target substrate is that the target substrate is spared from the high-temperature processing conditions under which TMD monolayers can be grown. High-temperature TMD growth conditions can damage the substrate upon which the TMDs are grown and, if the TMDs are grown on the same substrate upon which integrated circuit dies are fabricated, the TMD growth process can consume a large portion of the limited thermal budget of a semiconductor device processing flow.

One challenge in transferring TMD monolayers from a growth substrate to a target substrate is avoiding damage to the TMD monolayer during layer transfer. Transferring a TMD monolayer from a growth substrate adds complexity to a semiconductor manufacturing process and excessing handling of a TMD monolayer can cause damage to the TMD monolayer in the form of cracks, wrinkles, and voids. One source of damage to TMD monolayers during layer transfer is carrier wafer strain that can be transferred to the TMD monolayer during mechanical lift-off of the carrier wafer and TMD monolayer from a growth substrate.

Disclosed herein is a TMD monolayer transfer technology that forgoes the use of a temporary carrier wafer and directly transfers a TMD monolayer from a growth substrate to a target substrate. After growth of a TMD monolayer on a growth substrate and formation of a protective layer on top of the TMD monolayer, the growth substrate stack (comprising the growth substrate, the TMD monolayer, and the protective layer) is attached to the target substrate through diffusion bonding of the growth substrate stack to the target substrate. The growth substrate is then separated from the protective layer and the resulting exposed surface of the TMD monolayer is covered by another layer. The layer transfer technologies disclosed herein can be used to build stacks comprising multiple TMD monolayers. These stacks can be used in the gate stack of nanoribbon FETs, with the TMD monolayers acting as channel regions for the nanoribbon FETS.

Direct transfer of TMD monolayers from growth substrates to a target substrate has at least the following advantages. First, it involves fewer processing steps than layer transfer processing flows comprising two transfers of a TMD monolayer—a first transfer from the growth substrate to a carrier wafer and a second transfer from the carrier wafer to the target substrate. A simpler processing flow can result in reduced processing flow costs. Second, the reduced process complexity can result in higher quality transferred TMD monolayers due to the lesser handling of TMD monolayers.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or in any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, or positions that vary slightly from the meaning of the unmodified term. For example, the portion of a first layer or feature that is substantially perpendicular to a second layer or feature can include a first layer or feature that is +/−20 degrees from a second layer or feature, a first surface that is substantially parallel to a second surface can include a first surface that is within several degrees of parallel from the second surface, and a layer that is substantially planar can include layers that comprise some dishing, bumps, or other non-planar features resulting from processing variations and/or limitations. Further, a first layer that is substantially coplanar with another second layer includes first layers that are offset by a small amount due to processing variations and limitations. Moreover, a stated value for a dimension, feature, or characteristic qualified by the term “about” includes values within +/−10% of the stated value. Similarly, a stated range of values for a dimension, feature, or characteristic includes values within 10% of the listed upper and lower values for the range.

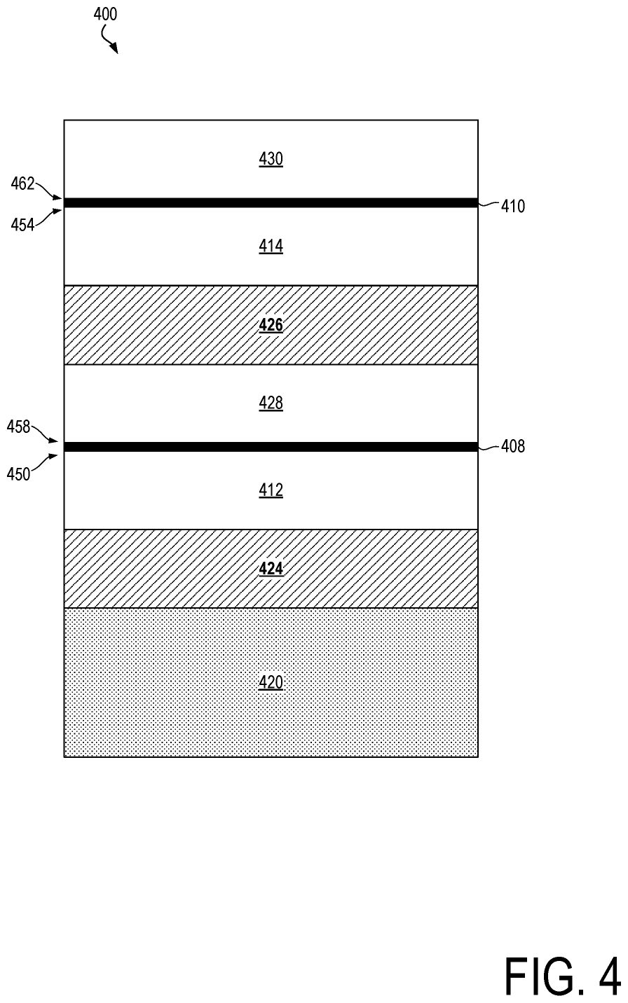

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. For example, with reference to FIG. 4, the TMD monolayer 408 is located on the target substrate 420 with intervening layers 412 and 424.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

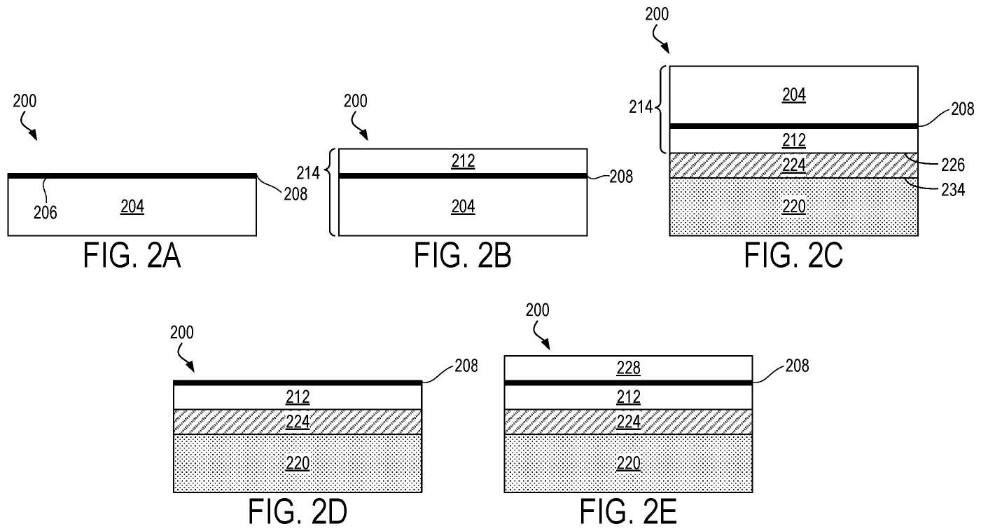

As used herein, the phrase “positioned between” in the context of a first layer or component positioned between a second layer or component and a third layer or component refers to the first layer or component being directly physically attached to the second and/or third parts or components (no layers or components between the first and second layers or components or the first and third layers or components) or physically attached to the second and/or third layers or components via one or more intervening layers or components. For example, with reference to FIG. 4, the layer 426 is positioned between layers 414 and 428, and with reference to FIG. 2C, the TMD monolayer 208 is positioned between the target substrate 220 and the growth substrate 204 with a protective layer 212 and a diffusion bonding layer 224 positioned between the TMD monolayer 208 and the target substrate 220.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “integrated circuit component” refers to a packaged or unpackaged integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims.

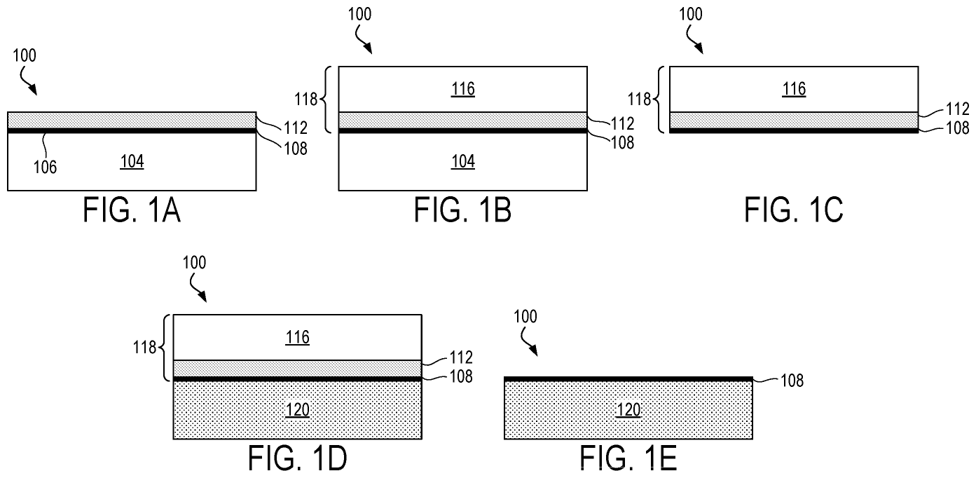

FIGS. 1A-1E are cross-sectional views of a simplified example processing flow of transferring a transition metal dichalcogenide (TMD) monolayer from a growth substrate to a target substrate involving two transfers of the TMD monolayer. Any of the fabrication methods or processes described herein, including method 600, may be performed using any suitable microelectronic fabrication techniques. For example, film deposition-such as depositing layers, filling (backfilling) portions of layers (e.g., filling removed portions of layers or removed layers), and filling via or contact openings may be performed using any suitable deposition techniques, including, for example, chemical vapor deposition (CVD), metalorganic chemical vapor deposition (MOCVD), molecular beam epitaxy (MBE), atomic layer deposition (ALD), sputtering and/or physical vapor deposition (PVD). Moreover, layer patterning-such as dielectric or metal layer patterning may be performed using any suitable techniques, such as photolithography-based patterning and etching (e.g., dry etching or wet etching).

FIG. 1A is a cross-sectional view of an example structure comprising a TMD monolayer 108 formed on a surface 106 of a growth substrate 104, with a protective layer 112 formed on the TMD monolayer 108. The TMD monolayer 108 is positioned between the protective layer 112 and the growth substrate 104.

TMDs have the chemical formula MX₂ where M is a transition metal and X is a chalcogen. A TMD monolayer comprises a middle layer of M atoms sandwiched between two layers of X atoms. TMD monolayers, which can also be referred to as 2D TMD layers, are less than 1 nanometer thick. The TMD monolayers disclosed in any of the embodiments described or referenced herein can comprise titanium, molybdenum, tungsten, platinum, erbium, lanthanum, rhodium, niobium, or another transition metal; with sulfur, selenium, or tellurium as the chalcogen. That is, in some embodiments, the TMD monolayers described or referenced herein can be molybdenum disulfide (MoS₂), molybdenum diselenide (MoSe₂), molybdenum ditelluride (MoTe₂), titanium disulfide (TiS₂), titanium diselenide (TiSe₂), titanium ditelluride (TiTe₂), tungsten disulfide (WS2), tungsten diselenide (WSe2), tungsten ditelluride (WTe₂), platinum disulfide (PtS₂), platinum diselenide (PtSe2), platinum ditelluride (PtTe₂), erbium disulfide (ErS₂), erbium diselenide (ErSe2), erbium ditelluride (ErTe2), rhodium disulfide (RhS₂), rhodium diselenide (RhSe₂), rhodium ditelluride (RhTe₂), lanthanum disulfide (LaS₂), lanthanum diselenide (LaSe₂), lanthanum ditelluride (LaTe₂), niobium disulfide (NbS2), niobium diselenide (NbSe2), niobium ditelluride, or another disulfide, disulfide, or ditelluride TMD.

In some embodiments, the TMD monolayer comprises a TMD alloy of the form ABX₂ where A and B are transition metals and X is a chalcogen. Thus, in some embodiments, the TMD monolayer can be, for example, Mo₍₁₋ₓ₎WₓS₂, Mo₍₁₋ₓ₎WₓSe₂, or W₍₁₋ₓ₎NbₓS₂.

In any of the embodiments described or referenced herein, the growth substrate can comprise sapphire, silicon, silicon with a layer (e.g., silicon dioxide (SiO₂), silicon carbide, graphene) on top of a bulk silicon region or other suitable material.

FIG. 1B is a cross-sectional view of the example structure 100 after attachment of a carrier wafer 116 to the protective layer 112. A carrier wafer stack 118 comprises the carrier wafer 116, the protective layer 112, and the TMD monolayer 108. The carrier wafer stack 118 further comprises a bonding layer (not shown), such as SiO₂, Si₃N₄, or another suitable material to enable attachment of the carrier wafer 116 to the protective layer 112. In any of the embodiments described or referenced herein, the carrier wafer 116 can be a wafer, panel, or other structure that provides mechanical support to layers, features, or components attached to the carrier wafer 116. The carrier wafer 116 can comprise silicon, glass, sapphire, plastic, silicon carbide (SiC), gallium arsenide (GaAs), or other suitable material.

FIG. 1C is a cross-sectional view of the example structure 100 after mechanical exfoliation of the carrier wafer stack 118 from the growth substrate 104. Mechanical exfoliation (or separation) of the carrier wafer stack 118 from the growth substrate 104 can comprise mechanical lift-off of the carrier wafer stack 118 from the growth substrate 104.

FIG. 1D is a cross-sectional view of the example structure 100 after attachment of the carrier wafer stack 118 to a target substrate 120. The carrier wafer stack 118 can be attached to the carrier wafer stack 118 via bonding, such as by fusion, vacuum, or thermo-compression bonding. The target substrate 120 can be a substrate on which transistors and/or other features into which the TMD monolayer 108 is to be integrated. In any of the embodiments described or referenced herein, a target substrate can comprise a crystalline substrate formed using a bulk silicon or a silicon-on-insulator (SOI) substructure. In some embodiments, the target substrate 120 may be formed using alternative materials, which may or may not be combined with silicon, that include, but are not limited to, germanium. Further materials classified as group II-VI, III-V, or IV may also be used to form the target substrate 120. Although a few examples of materials from which the target substrate 120 may be formed are described here, any material that may serve as a foundation for an integrated circuit device may be used.

FIG. 1E is a cross-sectional view of the example structure 100 after release of the carrier wafer 116 from the carrier wafer stack 118 and removal of the protective layer 112 from the TMD monolayer 108. The carrier wafer bonding layer and the protective layer 112 are removed along with the protective layer 112.

FIGS. 2A-2E are cross-sectional views of a simplified example processing flow of directly transferring a first TMD monolayer from a growth substrate to a target substrate. FIG. 2A is a cross-sectional view of an example structure comprising a TMD monolayer 208 formed on a surface 206 of a growth substrate 204. In some embodiments, the TMD monolayer 208 can be epitaxially grown on the surface 206 of the growth substrate 204.

FIG. 2B is a cross-sectional view of the example structure 200 after formation of a protective layer 212 on the TMD monolayer 208. In some embodiments, the protective layer 212 can be deposited on the TMD monolayer 208. The protective layer 212 can protect the TMD monolayer 208 from subsequent processing steps, such as physical vapor deposition (PVD), which can be used to form the layers used to bond the growth substrate stack 214 (comprising the growth substrate 204, the TMD monolayer 208, and the protective layer 212) to the target substrate, as will be discussed below. The TMD monolayer 208 is positioned between the protective layer 212 and the growth substrate 204. In any of the embodiments described or referenced herein, the protective layer 212 can comprise oxygen.

FIG. 2C is a cross-sectional view of the example structure 200 after bonding of the growth substrate stack 214 to the target substrate 220 via a diffusion bonding layer 224. In some embodiments, the bonding of the growth substrate stack 214 to the target substrate 220 is performed as follows. Diffusion bonding sub-layers that will ultimately form the diffusion bonding layer 224 are formed on a surface 226 of the protective layer 212 that is opposite the surface of the protective layer 212 attached to the TMD monolayer 208 and a surface 234 of the target substrate 220. The diffusion bonding sub-layers are then diffusion bonded to create diffusion bonding layer 224. In some embodiments, the diffusion bonding sub-layers are bonded by placing the growth substrate stack 214 and the target substrate 220 in a high vacuum chamber, sputtering the diffusion bonding sub-layers on protective layer surface 226 and target substrate surface 234, and bringing the surfaces 226 and 234 into contact with each other, while still under vacuum, for a sufficient length of time to induce a diffusion bond between the diffusion bonding sub-layers to create a single bonding layer, diffusion bonding layer 224. In some embodiments, the thickness of each of the diffusion bonding sub-layers can be in the range of about 1-2 nanometers and the diffusion bonding layer 224 can have a thickness of about 2-4 nanometers. In some embodiments, the diffusion bonding layer 224 can have a thickness of about 5 nanometers or less. In some embodiments, the diffusion bonding layer 224 is annealed after being created.

In any of the embodiments described or referenced herein, the diffusion bonding layer can comprise aluminum oxide (Al₂O₃, a material comprising aluminum and oxygen), yttrium oxide (Y₂O₃, a material comprising yttrium and oxygen), zirconium dioxide (ZrO₂, a material comprising zirconium and oxygen), tungsten trioxide (WO₃, a material comprising tungsten and oxygen), titanium dioxide (TiO₂, a material comprising titanium and oxygen), zinc oxide (ZnO, a material comprising zinc and oxygen), niobium pentoxide (Nb₂O₅, a material comprising niobium and oxygen), hafnium oxide (HfO₂, a material comprising hafnium and oxygen), amorphous silicon, gold, silver, titanium, zirconium, another weldable metal, or another suitable material.

In any of the embodiments here, the diffusion bonding layer can also comprise a material with a gradient oxidation to create a diffusion bonding layer with oxygen phase-controlled conductivity that can be used as in the gate electrode region in a field effect transistor (FET), such as a nanoribbon FET utilizing transferred TMD monolayers as its channel regions. Such diffusion bonding layers can comprise, for example, niobium and oxygen (e.g., Nb₂O₅ and NbO (niobium pentoxide and niobium oxide)), tantalum and oxygen (Ta₂O₅, TaO, and TaO₂ (tantalum pentoxide, TaO, and tantalum dioxide)), vanadium and oxygen (V₂O₅ and VO₂ (vanadium pentoxide and vanadium dioxide)). An oxidation gradient in a diffusion bonding layer can be evidenced by the diffusion bonding layer having a first atomic composition of oxygen at a first location in the diffusion bonding layer and a second atomic composition of oxygen at a second location in the diffusion bonding layer, the first atomic composition of oxygen greater than the second atomic composition of oxygen, the first location in the diffusion bonding layer further away from the surface of a TMD monolayer than the second location in the diffusion bonding layer.

The target substrate 220 can be a substrate on which transistors and/or other features into which the TMD monolayer 208 is to be integrated. In any of the embodiments described or referenced herein, a target substrate can comprise a crystalline substrate formed using a bulk silicon or a silicon-on-insulator (SOI) substructure. In some embodiments, the target substrate 220 may be formed using alternative materials, which may or may not be combined with silicon, that include, but are not limited to, germanium. Further materials classified as group II-VI, III-V, or IV may also be used to form the target substrate 220. Although a few examples of materials from which the target substrate 220 may be formed are described here, any material that may serve as a foundation for an integrated circuit device may be used.

FIG. 2D is a cross-sectional view of the example structure 200 after release of the growth substrate 204 from the TMD monolayer 208. Release of the growth substrate 204 can be performed by mechanically cleaving the growth substrate 204 from TMD monolayer 208.

FIG. 2E is a cross-sectional view of the example structure 200 after formation of a layer 228 on the TMD monolayer 208. In some embodiments, the layer 228 is a sacrificial layer that is replaced by one or more functional layers during subsequent processing, such as by a gate dielectric layer and one or more gate metal electrode layers, as will be discussed in more detail below. In some embodiments, the layer 228 is not a sacrificial layer and comprises one or more functional layers that form, for example, part of an active device, such as a field effect transistor. In some embodiments, the layer 228 can comprise oxygen.

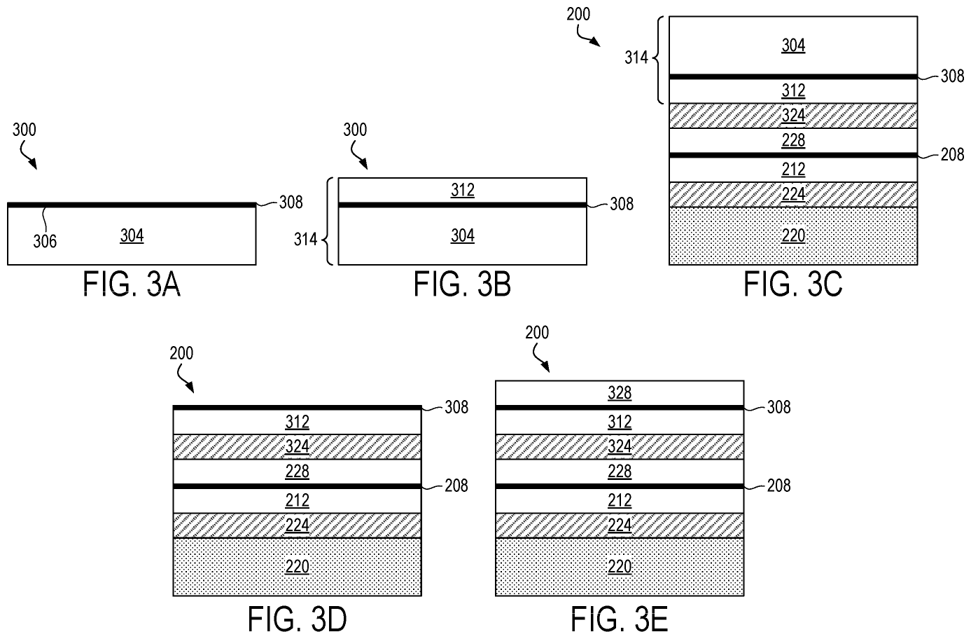

FIGS. 3A-3E are cross-sectional views of a simplified example processing flow of transferring a second transition metal dichalcogenide (TMD) monolayer from a growth substrate to the target substrate of FIGS. 2C-2E. Features or structures in FIGS. 3A-3E having similar numbers as in FIGS. 2A-2E (e.g., 308 and 208, 312 and 212) can comprise any of the materials described above as being used in the corresponding feature or structure in FIGS. 2A-2E.

FIG. 3A is a cross-sectional view of a structure 300 comprising a second TMD monolayer 308 formed on a surface 306 of a growth substrate 304, with a protective layer 312 formed on the TMD monolayer 308. FIG. 3B is a cross-sectional view of the structure 300 after attachment of a protective layer 312 on the TMD monolayer 308. A growth substrate stack 314 comprises the growth substrate 304, the TMD monolayer 308, and the protective layer 312.

FIGS. 3C-3E illustrate the transfer of the second TMD monolayer 308 to the structure 200 of FIG. 2E to create a two-layer stack of TMD monolayers. FIG. 3C illustrates the structure 200 of FIG. 2E after bonding of the growth substrate stack 314 to the target substrate 220 via a diffusion bonding layer 324. The diffusion bonding layer 324 can be created in the same manner as the diffusion bonding layer 224 as discussed above. FIG. 3D is a cross-sectional view of the structure 200 after release of the growth substrate 304 from the TMD monolayer 308. FIG. 3E illustrates the structure 200 after formation of a layer 328 on the TMD monolayer 308, which may be a sacrificial layer or a functional layer, as discussed above with regard to layer 228. In some embodiments, additional TMD monolayers can be grown on a growth substrate and transferred to the target substrate 220 to fabricate a TMD monolayer stack comprising more than the two TMD monolayers (208, 308) illustrated in FIG. 3E. In some embodiments, a TMD monolayer stack formed from transferred TMD monolayers can comprise five or more TMD monolayers.

FIG. 4 illustrates an example structure comprising a TMD monolayer stack formed by direct transfer of TMD monolayers from growth substrates to a target substrate. The structure 400 comprises TMD monolayers 408 and 410 positioned above a target substrate 420. Layers 424 and 412 are positioned between the target substrate 420 and the monolayer 408; layers 428, 426, and 414 are positioned between the monolayers 408 and 410; and a layer 430 is positioned above and adjacent to the monolayer 410. Layers 424 and 426 are diffusion bonding layers. Layer 424 is a diffusion bonding layer formed during bonding of a first growth substrate stack comprising TMD monolayer 408 to the target substrate 420 and layer 426 is a diffusion bonding layer formed during bonding a second growth substrate stack comprising TMD monolayer 410 to the target substrate. Layers 412 and 414 are protective layers formed on TMD monolayers 408 and 410, respectively, prior to transfer of the TMD monolayers 408 and 410 to the target substrate 220. Layers 428 and 430 are layers formed on the exposed surfaces of the TMD monolayer 408 and 410, respectively, after removal of the growth substrates from the TMD monolayers 408 and 410 during layer transfer.

In some embodiments, transfer of a TMD monolayer from a growth substrate to a target substrate can be evidenced by the absence of chalcogen (e.g., sulfur, selenium, or tellurium) residue at the interface between the TMD monolayer and the layer formed on the TMD monolayer after transfer of the TMD monolayer to the target substrate and separation of the growth substrate from the TMD monolayer and the interface between the TMD monolayer and the layer positioned adjacent to the TMD monolayer and between the TMD monolayer and the target substrate after transfer of the growth substrate stack to the target substrate. For example, with reference to FIG. 4, the chalcogen of TMD monolayers 408 and 410 may not be present in the layer 428 (either near an interface 458 between the TMD monolayer 408 and the layer 428 or anywhere in the layer 428), the layer 430 (near an interface 462 between the TMD monolayer 410 and layer 430 or anywhere in the layer 430), the layer 412 (near an interface 450 between the TMD monolayer 408 and layer 412 or anywhere in the layer 412), and the layer 414 (near an interface 454 between the TMD monolayer 410 and layer 414 or anywhere in the layer 414). In some embodiments, the absence of TMD chalcogen residue at an interface or in a layer can be indicated by an atomic composition of 0.1% or less of the TMD chalcogen at the interface or the layer.

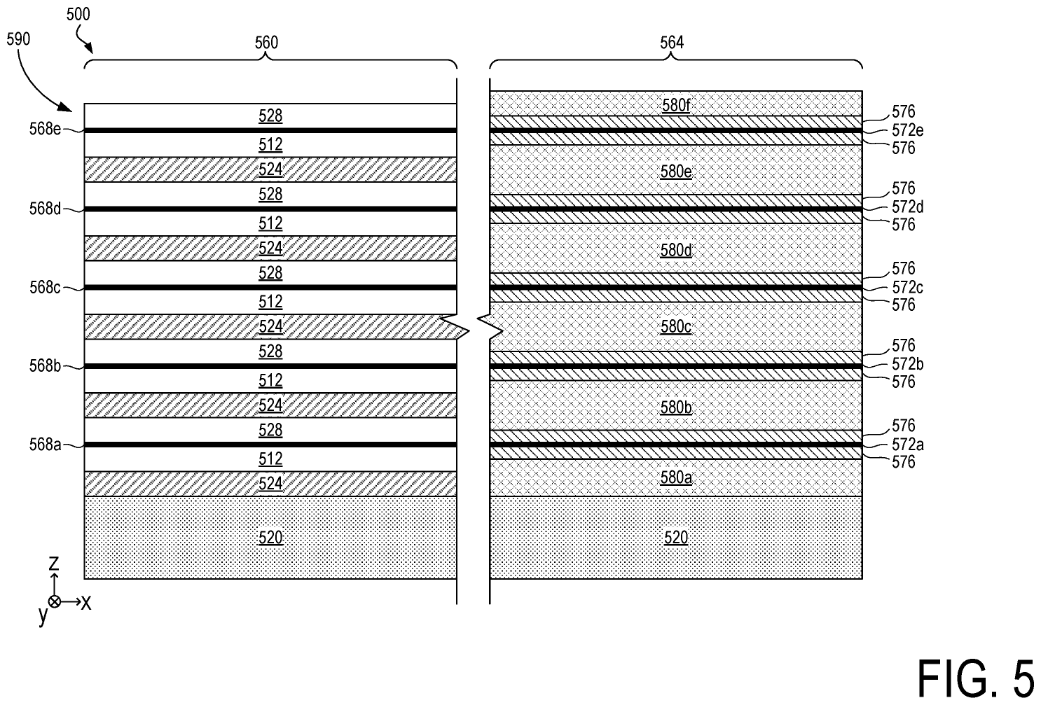

FIG. 5 is a cross-sectional view of an example integrated circuit die comprising two TMD monolayer stacks. The integrated circuit die 500 comprises first TMD monolayer stack 560 and second TMD monolayer stack 564 positioned above a target substrate 520. Stacks 560 and 564 comprise five TMD monolayers 568 (568a-568e) and 572 (572a-572e), respectively. TMD monolayer stack 560 is located in a buffer region the integrated circuit die 500 and TMD monolayer stack 564 is part of a nanoribbon field effect transistor (FET). The channel region of the nanoribbon FET comprises the TMD monolayers 572. The buffer region of the integrated circuit die 500 is a region at the periphery of the integrated circuit die 500 and does not comprise nanoribbon transistors comprising TMD monolayers. The TMD monolayer stack 560 is thus positioned laterally between a transistor utilizing TMD monolayers, such as the nanoribbon transistor employing the gate stack 564 and an integrated circuit die edge, such as die edge 590.

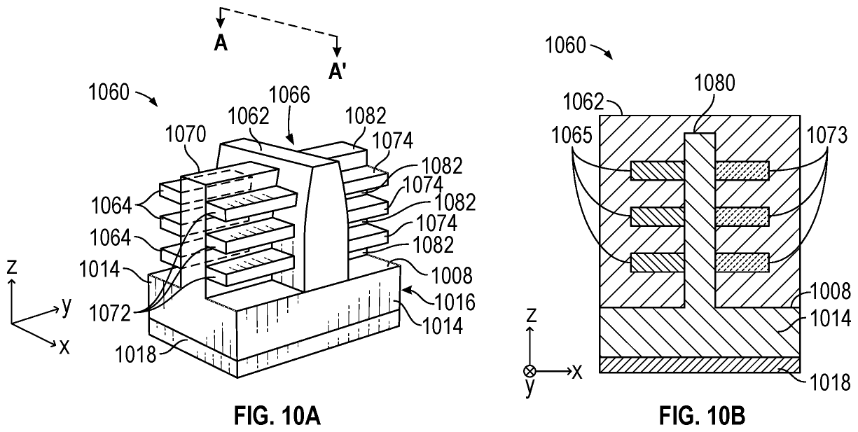

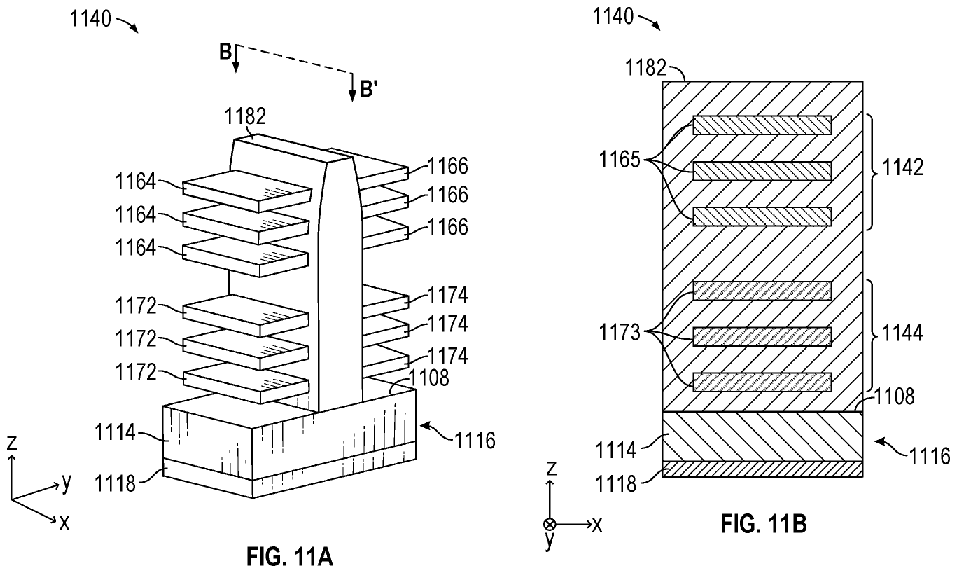

Although FIG. 5 illustrates a TMD monolayer stack 564 used in a nanoribbon FET, TMD monolayer stacks can be used in other types of transistor architectures, such as forksheet or complementary FET (CFET) transistors, as illustrated in FIGS. 10A-10B and FIGS. 11A-11B, respectively.

The pairs of TMD monolayers 568 and 572 that are illustrated as being vertically aligned in FIG. 5 can be portions of a transferred TMD monolayer. For example, TMD monolayers 568a and 572a can be portions of a first transferred TMD monolayer and TMD monolayers 568b and 572b can be portions of a second transferred TMD monolayer. As such, TMD monolayers illustrated as being vertically aligned in FIG. 5 are substantially coplanar. For example, TMD monolayer 568a is substantially coplanar with TMD monolayer 572a and TMD monolayer 568b is substantially coplanar with TMD monolayer 572b.

The TMD monolayer stack 560 comprises layers 512, layers 528, and diffusion bonding layers 524. A layer 512 is positioned below and adjacent to a TMD monolayer 568, and a diffusion bonding layer 524 is positioned adjacent to a layer 512. A layer 528 is positioned above and adjacent to a TMD monolayer 568. For pairs of TMD monolayers 568 positioned vertically adjacent to each other (e.g., 568b and 568c), a diffusion bonding layer 524, a layer 512, and a layer 528 are positioned between pairs of the TMD monolayer 568, with the diffusion bonding layer 524 positioned between the layer 512 and the layer 528.

As mentioned above, a nanoribbon FET included in the integrated circuit die 500 can comprise the TMD monolayer stack 564, with the channel regions of the nanoribbon FET comprising the TMD monolayers 572. In some embodiments, as part of forming the gate stack of the nanoribbon FET, the layers formed between and adjacent to the TMD monolayers 572 as part of the layer transfer process (e.g., layers 512, 524, and 528) can be replaced with layers that function as gate dielectric layers and gate electrode regions of the nanoribbon FET. Gate dielectric layers 576 are formed adjacent to top and bottom surfaces of the individual TMD monolayers 572 and gate electrode regions 580 are formed on the gate dielectric layers 576. For example, gate electrode regions 580b, 580c, 580d, and 580e are positioned between and adjacent to the gate dielectric layers 576 attached to vertically adjacent TMD monolayers 572 (e.g., 572b and 572c), gate electrode region 580f is positioned above and adjacent to the topmost gate dielectric layer 576e, and gate electrode region 580a is positioned below and adjacent to the bottommost gate dielectric layer 576a.

In some embodiments, the as-formed diffusion bonding layers 524 and the layers 512 and 524 are functional layers. That is, they are not replaced during subsequent processing to form layers used in active or other devices, such as nanoribbon FETs. For example, each of the layers 512 and 528 can comprise one or more layers comprising materials that are functional as a gate dielectric layers in a nanoribbon FET and each of the layers 524 can comprise one or more layers that are functional as a gate electrode regions in a nanoribbon FET. For example, the diffusion bonding layers 524 are utilized as the gate electrode regions 580 and layers 512 and 528 are utilized as the gate dielectric layers 576. In some embodiments, the layers 524 can comprise diffusion bonding layers having a gradient oxidation state to create a functional gate electrode region with phase-controller conductivity. As described above, such diffusion bonding layers can comprise niobium and oxygen (e.g., Nb₂O₅ and NbO (niobium pentoxide and niobium oxide)), tantalum and oxygen (Ta₂O₅, TaO, and TaO₂ (tantalum pentoxide, TaO, and tantalum dioxide)), vanadium and oxygen (V₂O₅ and Vo₂ (vanadium pentoxide and vanadium dioxide)).

The gate dielectric layers 576 can comprise one or more layers comprising any of the materials that can be part of any gate dielectric layer described or referenced herein, such as the gate dielectric of gate 822. The gate electrode regions 580 can comprise any material that can be part of any gate electrode for any transistor described herein, such as the gate electrode region of gate 822 for a p-type (PMOS) transistor or an n-type (NMOS) transistor.

The interfaces between the TMD monolayers 572 and the layers 576 and the interfaces between the TMD monolayers 568 and the layers 528 are devoid of chalcogen residue. That is, these interfaces (and the layers 576 and 528) do not comprise the chalcogen used in the TMD monolayers 568 and 572 or have an atomic composition of 0.1% or less of the chalcogen used in the TMD monolayers 568 and 572.

As discussed above, the thickness of the diffusion bonding layers 524 can be about 5 nanometers or less in some embodiments. This thickness can be less than the thickness of a protective layer formed on a target substrate upon which a TMD monolayer is grown to protect the target substrate from high-temperature TMD monolayer growth conditions.

In some embodiments, the integrated circuit die 500 can comprise TMD monolayer stacks 560 that have diffusion bonding layers 524 between TMD monolayers in regions of the integrated circuit die 500 other than in a peripheral buffer region. A TMD monolayer stack 560 can be located in any region of an integrated circuit die where there are not transistors or other devices employing transferred TMD monolayers.

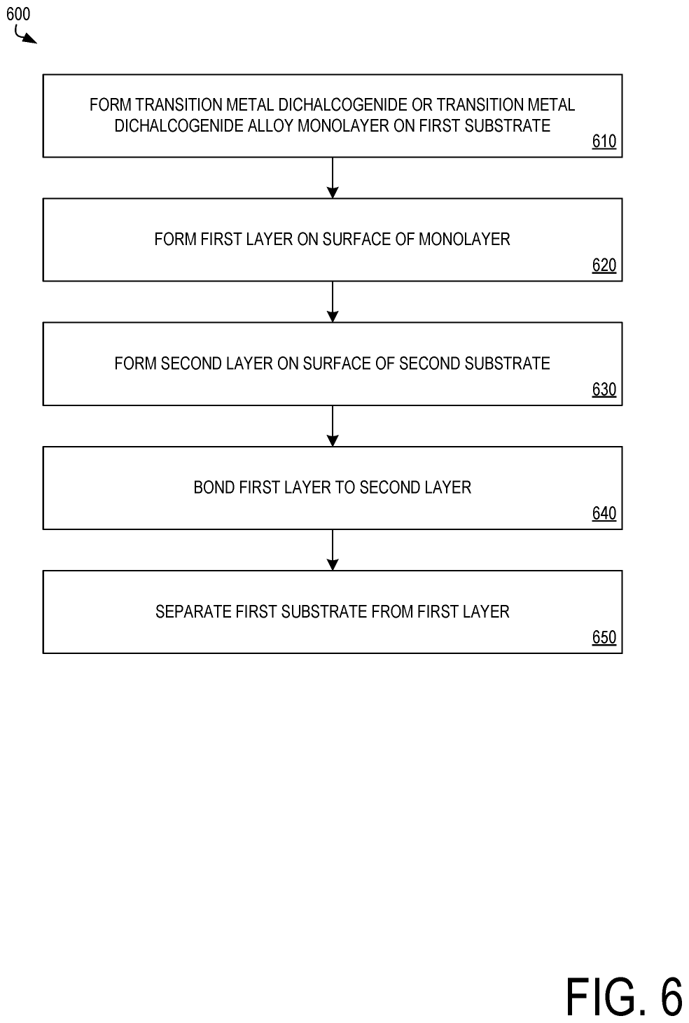

FIG. 6 is an example method of directly transferring a TMD monolayer from a growth substrate to a target substrate. The method 600 can be performed by an integrated circuit component manufacturer. At 610, a monolayer is formed on a first substrate, the monolayer comprising a transition metal dichalcogenide. At 620, a first layer is formed on a surface of the monolayer. At 630, a second layer is formed on a surface of a second substrate. At 640, the first layer is bonded to the second layer. At 650, the first substrate is separated from the first layer.

The integrated circuit components and microelectronic structures or assemblies described herein can be used in any processor unit or integrated circuit component described or referenced herein. An integrated circuit component comprising embedded alignment markers can be attached to a printed circuit board (motherboard, mainboard). In some embodiments, one or more additional integrated circuit components or other components (e.g., battery, memory, antenna) can be attached to the printed circuit board. In some embodiments, the printed circuit board and the integrated circuit component can be located in a computing device that comprises a housing that encloses the printed circuit board and the integrated circuit component.

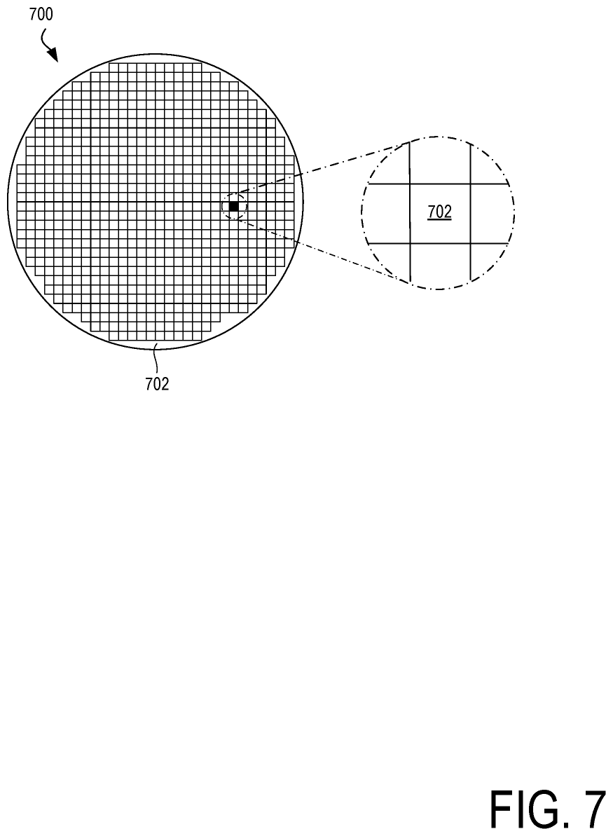

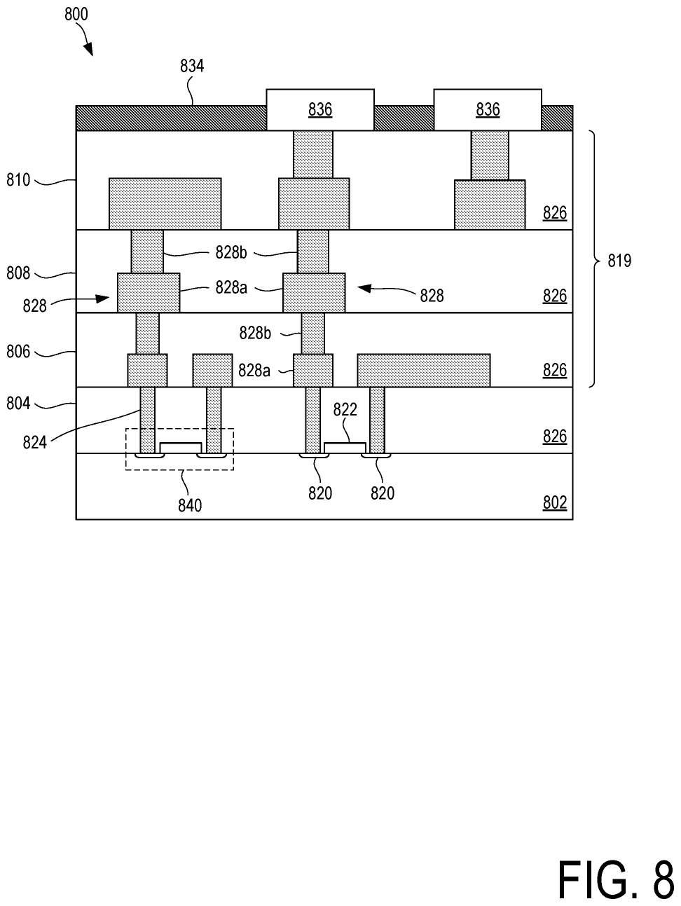

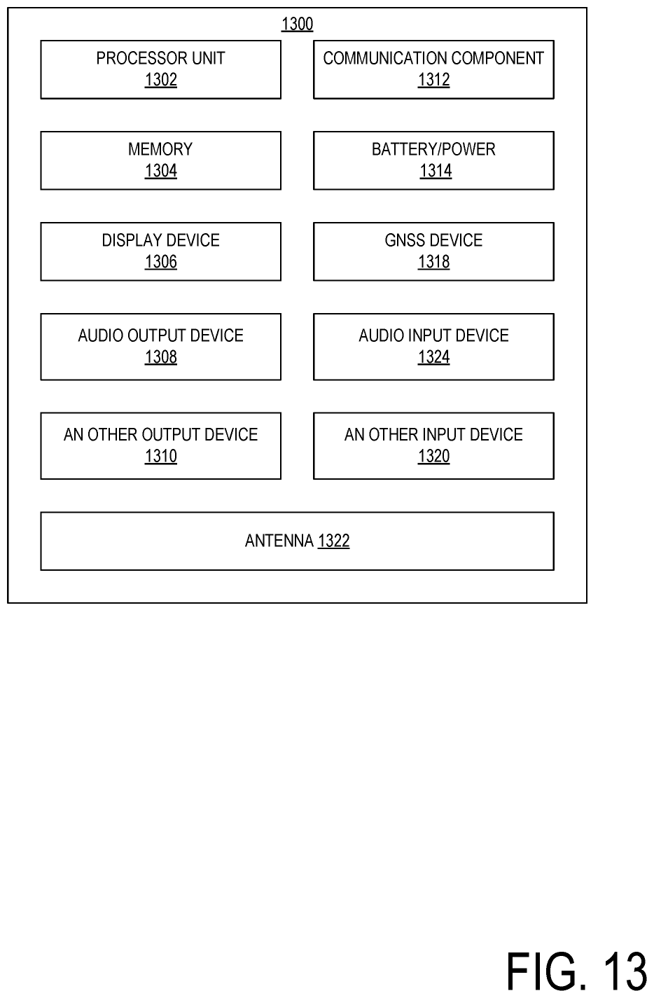

FIG. 7 is a top view of a wafer 700 and dies 702 that may be included in any of the microelectronic assemblies disclosed herein (e.g., die 500). The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may be any of the dies disclosed herein. The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 1302 of FIG. 13) or other logic that is configured to store information in the memory devices or execute instructions stored in the memory array. Various ones of the microelectronic assemblies disclosed herein may be manufactured using a die-to-wafer assembly technique in which some dies are attached to a wafer 700 that include others of the dies, and the wafer 700 is subsequently singulated.

FIG. 8 is a cross-sectional side view of an integrated circuit device 800 that may be included in any of the microelectronic assemblies disclosed herein. One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, carbon, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

FIGS. 9A-9D are simplified perspective views of example planar, FinFET, gate-all-around, and stacked gate-all-around transistors. The transistors illustrated in FIGS. 9A-9D are formed on a substrate 916 having a surface 908. Isolation regions 914 separate the source and drain regions of the transistors from other transistors and from a bulk region 918 of the substrate 916.

FIG. 9A is a perspective view of an example planar transistor 900 comprising a gate 902 that controls current flow between a source region 904 and a drain region 906. The transistor 900 is planar in that the source region 904 and the drain region 906 are planar with respect to the substrate surface 908.

FIG. 9B is a perspective view of an example FinFET transistor 920 comprising a gate 922 that controls current flow between a source region 924 and a drain region 926. The transistor 920 is non-planar in that the source region 924 and the drain region 926 comprise “fins” that extend upwards from the substrate surface 928. As the gate 922 encompasses three sides of the semiconductor fin that extends from the source region 924 to the drain region 926, the transistor 920 can be considered a tri-gate transistor. FIG. 9B illustrates one S/D fin extending through the gate 922, but multiple S/D fins can extend through the gate of a FinFET transistor.

FIG. 9C is a perspective view of a gate-all-around (GAA) transistor (GAAFET) 940 comprising a gate 942 that controls current flow between a source region 944 and a drain region 946 of a strip 948 comprising a semiconductor (semiconductor strip). The transistor 940 is non-planar in that the strip 948 is elevated from the substrate surface 908.

FIG. 9D is a perspective view of a GAA transistor 960 comprising a gate 962 that controls current flow between source regions 964 and drain regions 966 of multiple elevated semiconductor strips 968. The transistor 960 is a stacked GAA transistor as the gate controls the flow of current between multiple elevated S/D regions stacked on top of each other. The transistors 940 and 960 can be referred to as gate-all-around transistors as the gates encompass all sides of the portions of the semiconductor strips that extend from the source regions to the drain regions. The transistors 940 and 960 can alternatively be referred to as nanowire, nanosheet, or nanoribbon transistors and the semiconductor strips that pass through the gate region can be referred to as nanowires, nanowires, or nanoribbons.

FIGS. 10A and 10B are simplified perspective and cross-sectional views of example forksheet gate-all-around transistors. The forksheet transistors 1060 are formed on a substrate 1016 having a surface 1008. The substrate 1016 comprises an isolation region 1014 located on top of a bulk region 1018. The forksheet transistors 1060 are similar to the stacked GAA transistor 960 of FIG. 9D, but with an isolation wall (comprising isolation regions 1070, 1080, and 1082) located between stacked n-type and p-type source regions and stacked n-type and p-type drain regions. The forksheet transistors 1060 comprise a gate 1062 that controls flow between multiple n-type elevated source regions 1064 and multiple n-type elevated drain regions 1066, and multiple p-type elevated source regions 1072 and multiple p-type elevated drain regions 1074. FIG. 10B is a cross-sectional view of the forksheet transistors 1060 taken along the line A-A′ of FIG. 10A. Channel regions 1065 connect n-type source regions 1064 to n-type drain regions 1066, channel regions 1073 connect p-type source regions 1072 to p-type drain regions 1074, and isolation region 1080 separates the channel regions 1065 from the channel regions 1073 and connects isolation region 1070 to isolation region 1082. Thus, the forksheet transistors 1060 comprise an n-type transistor comprising n-type source regions 1064, channel region 1065, n-type drain regions 1066 and gate 1062; and a p-type transistor comprising p-type source regions 1072, channel regions 1074, p-type drain regions 1073, and gate 1062. The gate 1062 is shared by the forksheet transistors 1060. Forksheet transistors 1060 can provide for reduced spacing between n-type and p-type S/D regions in adjacent transistors relative to GAA transistors and can thus allow for increased transistor density relative to GAA transistors or increased active transistor width at the same transistor density as GAA transistors.

FIGS. 11A-11B are simplified perspective and cross-sectional views, respectively, of an example complementary field-effect-transistor (CFET) architecture. FIG. 11B is a cross-sectional view of the CFET architecture 1140 taken along the line B-B′ of FIG. 11A. The CFET architecture 1140 comprises vertically stacked gate-all-around transistors 1142 and 1144. In FIGS. 11A-11B, transistor 1142 is an n-type transistor and transistor 1144 is a p-type transistor, but in other embodiments, a CFET architecture can comprise an n-type transistor located above a p-type transistor. The transistors 1142 and 1144 are formed on a substrate 1116 having a surface 1108. The substrate 1116 comprises an isolation region 1114 located on top of a bulk region 1118.

The n-type and p-type transistors 1142 and 1144 comprise a gate 1182 shared by both transistors that controls current flow between multiple elevated source regions and multiple elevated drain regions 1174. The n-type transistor 1142 comprises n-type source regions 1172 connected to n-type drain regions 1174 by channel regions 1173 and the p-type transistor 1144 comprises p-type source regions 1164 connected to p-type drain regions 1166 by channel regions 1165. The transistor stacking employed by the CFET architecture can provide for improved transistor density in the x- and y-dimensions or increased transistor width at the same transistor density relative to other gate-all-around transistor architectures, such as those illustrated in FIGS. 9B, 11A, and 11B. In some embodiments, the CFET architecture 1140 can be formed monolithically, with the upper and lower transistors being formed on the same substrate, or sequentially, with the lower transistor (e.g., 1140) formed on a first substrate and the upper transistor (e.g., 1142) formed on a second substrate, with the upper transistor integrated with the lower transistor through transfer of the upper transistor from the second substrate to the first substrate.

Returning to FIG. 8, a transistor 840 may include a gate 822 formed of at least two layers, a gate dielectric, and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8 The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker than the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board). The integrated circuit device 800 may include additional or alternate structures to route the electrical signals from the interconnect layers 806-810; for example, the conductive contacts 836 may include other analogous features (e.g., posts) that route the electrical signals to external components.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. In some embodiments, TSVs extending through the substrate can be used for routing power and ground signals from conductive contacts on the opposite side of the integrated circuit device 800 from the conductive contacts 836 to the transistors 840 and any other components integrated into the integrated circuit device 800, and the metallization stack 819 can be used to route I/O signals from the conductive contacts 836 to transistors 840 and any other components integrated into the integrated circuit device 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

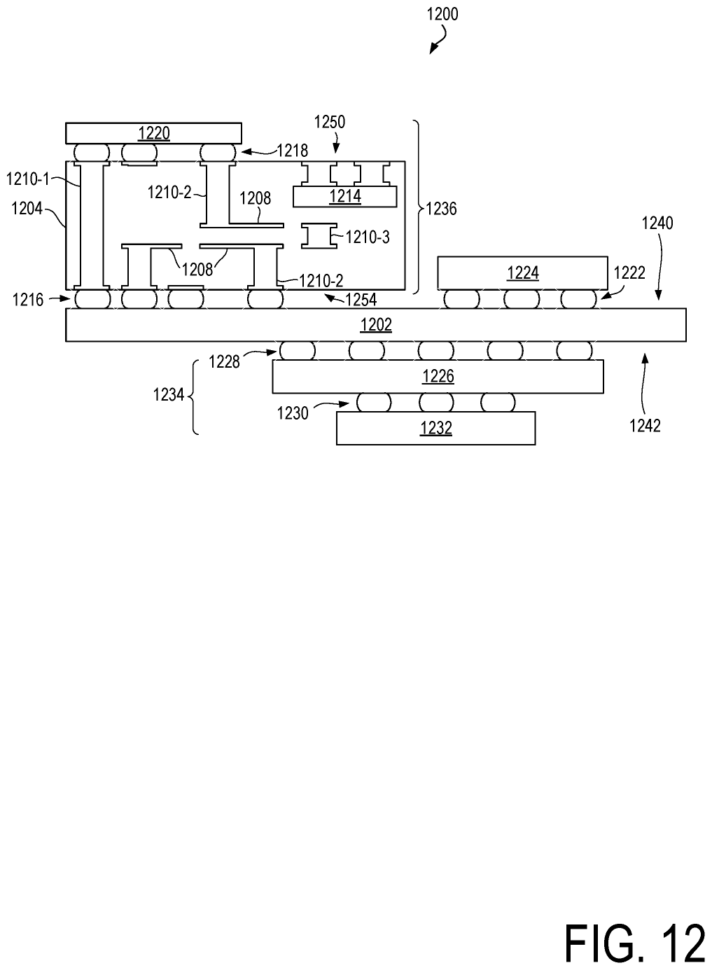

FIG. 12 is a cross-sectional side view of an integrated circuit device assembly 1200 that may include any of the microelectronic assemblies disclosed herein. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242. Any of the integrated circuit components discussed below with reference to the integrated circuit device assembly 1200 may take the form of any suitable ones of the embodiments of the microelectronic assemblies disclosed herein.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1216 may serve as the coupling components illustrated or described for any of the substrate assembly or substrate assembly components described herein, as appropriate.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpackaged integrated circuit product that includes one or more integrated circuit dies (e.g., the die 702 of FIG. 7, the integrated circuit device 800 of FIG. 8) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel@embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include integrated circuit die comprising TMD monolayers directly transferred from a growth layer and/or one or more of the microelectronic assemblies disclosed herein. For example, any suitable ones of the components of the electrical device 1300 may include one or more of the integrated circuit device assemblies 1200, integrated circuit components 1220, integrated circuit devices 800, or integrated circuit dies 702, 500 disclosed herein, and may be arranged in any of the microelectronic assemblies disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random-access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the 5 nano associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such as speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include an other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include an other input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C. Furthermore, as used in this application and the claims, a list of items joined by the term “one of” can mean any one of the listed items. For example, the phrase “one of A, B, and C” can mean A, B, or C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus comprising: a substrate; a monolayer positioned above the substrate, the monolayer comprising a transition metal dichalcogenide or transition metal dichalcogenide alloy; a first layer positioned adjacent to the monolayer and between the monolayer and the substrate; and a second layer positioned adjacent to the substrate and between the first layer and the substrate.

Example 2 comprises the apparatus of example 1, wherein the first layer comprises oxygen.

Example 3 comprises the apparatus of example 1 or 2, wherein the first layer comprises an atomic composition of about 0.1% or less of sulfur, selenium, or tellurium at an interface between the monolayer and the first layer.

Example 4 comprises the apparatus of example 1 or 2, wherein the first layer does not comprise sulfur, selenium, or tellurium.

Example 5 comprises the apparatus of any one of examples 1-4, wherein the second layer comprises aluminum and oxygen.

Example 6 comprises the apparatus of any one of examples 1-4, wherein the second layer comprises yttrium and oxygen.

Example 7 comprises the apparatus of any one of examples 1-4, wherein the second layer comprises zirconium and oxygen.

Example 8 comprises the apparatus of any one of examples 1-4, wherein the second layer comprises tungsten and oxygen.

Example 9 comprises the apparatus of any one of examples 1-4, wherein the second layer comprises titanium and oxygen.

Example 10 comprises the apparatus of any one of examples 1-4, wherein the second layer comprises zinc and oxygen.

Example 11 comprises the apparatus of any one of examples 1-4, wherein the second layer comprises amorphous silicon.

Example 12 comprises the apparatus of any of examples 1-4, wherein the second layer comprises gold, silver, titanium, or zirconium.

Example 13 comprises the apparatus of any one of examples 1-4, wherein the second layer comprises niobium and oxygen.

Example 14 comprises the apparatus of any one of examples 1-4, wherein the second layer comprises tantalum and oxygen.

Example 15 comprises the apparatus of any one of examples 1-4, wherein the second layer comprises vanadium and oxygen.

Example 16 comprises the apparatus of any one of examples 13-15, wherein the second layer comprises a first atomic composition of oxygen at a first location in the second layer and a second atomic composition of oxygen at a second location in the second layer, the first atomic composition greater than the second atomic composition, the first location in the second layer further away from a surface of the monolayer than the second location of the second layer.

Example 17 comprises the apparatus of any one of examples 1-16, wherein the substrate comprises silicon.

Example 18 comprises the apparatus of any one of examples 1-17, wherein the transition metal dichalcogenide comprises: a transition metal; and sulfur, selenium, or tellurium.

Example 19 comprises the apparatus of example 18, wherein the transition metal is titanium.

Example 20 comprises the apparatus of example 18, wherein the transition metal is molybdenum.

Example 21 comprises the apparatus of example 18, wherein the transition metal is tungsten.

Example 22 comprises the apparatus of example 18, wherein the transition metal is platinum.

Example 23 comprises the apparatus of example 18, wherein the transition metal is erbium.

Example 24 comprises the apparatus of example 18, wherein the transition metal is lanthanum.

Example 25 comprises the apparatus of example 18, wherein the transition metal is rhodium.

Example 26 comprises the apparatus of example 18, wherein the transition metal is niobium.

Example 27 comprises the apparatus of any one of examples 1-17, wherein the transition metal dichalcogenide alloy comprises: a first transition metal and a second transition metal; and sulfur, selenium, or tellurium.

Example 28 comprises the apparatus of example 27, wherein the first transition metal is titanium, molybdenum, tungsten, platinum, erbium, lanthanum, rhodium, or niobium; and the second transition metal is titanium, molybdenum, tungsten, platinum, erbium, lanthanum, rhodium, or niobium, the first transition metal different than the second transition metal.

Example 29 comprises the apparatus of any one of examples 1-28, further comprising a third layer positioned above and adjacent to the monolayer, wherein the third layer comprises oxygen.

Example 30 comprises the apparatus of any one of examples 1-29, wherein a thickness of the second layer is about 5 nanometers or less.

Example 31 comprises the apparatus of any one of examples 1-29, wherein a thickness of the second layer is in a range of about 2-4 nanometers.

Example 32 comprises the apparatus of any one of examples 1-31 wherein the monolayer is a first monolayer, the apparatus further comprising: a second monolayer positioned above the first monolayer, the second monolayer comprising the transition metal dichalcogenide or transition metal dichalcogenide alloy; a third layer positioned adjacent to the second monolayer and between the first monolayer and the second monolayer; and a fourth layer positioned adjacent to the third layer between the third layer and the first monolayer.

Example 33 comprises the apparatus of example 32, wherein the third layer comprises oxygen.

Example 34 comprises the apparatus of example 32 or 33, wherein the third layer comprises an atomic composition of about 0.1% or less of sulfur, selenium, or tellurium at an interface between the second monolayer and the third layer.

Example 35 comprises the apparatus of example 32 or 33, wherein the third layer does not comprise sulfur, selenium, or tellurium.

Example 36 comprises the apparatus of any one of examples 32-35, wherein a thickness of the fourth layer is about 5 nanometers or less.

Example 37 comprises the apparatus of any one of examples 32-35, wherein a thickness of the fourth layer is in a range of about 2-4 nanometers.

Example 38 comprises the apparatus of any one of examples 32-37, further comprising a fifth layer positioned above and adjacent to the second monolayer, wherein the fifth layer comprises oxygen.

Example 39 comprises the apparatus of any one of examples 1-31, further comprising a field effect transistor, wherein the first layer, the monolayer, and the field effect transistor are located in an integrated circuit die having a die edge, the first layer and the monolayer positioned laterally between the field effect transistor and the die edge.

Example 40 comprises the apparatus of any of examples 1-31 wherein the apparatus is an integrated circuit component comprising the monolayer, the first layer, the second layer, and the substrate.

Example 41 comprises the apparatus of example 40, wherein the integrated circuit component is attached to a printed circuit board.

Example 42 comprises the apparatus of example 41, wherein the integrated circuit component is a first integrated circuit component and one or more second integrated circuit components are attached to the printed circuit board.

Example 43 is an apparatus comprising: a substrate; a first monolayer positioned above the substrate comprising a transition metal dichalcogenide or a transition metal dichalcogenide alloy; a first layer positioned adjacent to the first monolayer and between the first monolayer and the substrate; a second layer positioned adjacent to the substrate and between the first layer and the substrate; a second monolayer positioned above the substrate, the second monolayer substantially coplanar with the first monolayer, the second monolayer comprising the transition metal dichalcogenide or transition metal dichalcogenide; a third layer positioned adjacent to the second monolayer and between the second monolayer and the substrate; and a fourth layer positioned adjacent to the substrate and between the third layer and the fourth layer, the fourth layer comprising a metal.

Example 44 comprises the apparatus of example 43, wherein the first layer comprises an atomic composition of about 0.1% or less of sulfur, selenium, or tellurium at an interface between the first monolayer and the first layer.

Example 45 comprises the apparatus of any one of examples 43-44, wherein a thickness of the second layer is about 5 nanometers or less.

Example 46 comprises the apparatus of any one of examples 43-44, wherein a thickness of the second layer is in a range of about 2-4 nanometers.

Example 47 comprises the apparatus of any one of examples 43-46, wherein the second layer comprises: aluminum and oxygen; yttrium and oxygen; zirconium and oxygen; tungsten and oxygen; titanium and oxygen; zinc and oxygen; niobium and oxygen; or amorphous silicon.

Example 48 comprises the apparatus of any of examples 43-46, wherein the second layer comprises gold, silver, titanium, or zirconium.

Example 49 comprises the apparatus of any one of examples 43-46, wherein the second layer comprises: niobium and oxygen; tantalum and oxygen; and vanadium and oxygen.

Example 50 comprises the apparatus of any one of examples 43-49, wherein the substrate comprises silicon.

Example 51 comprises the apparatus of any one of examples 43-50, wherein the transition metal dichalcogenide comprises: a transition metal; and sulfur, selenium, or tellurium.

Example 52 comprises the apparatus of example 51, wherein the transition metal is titanium, molybdenum, tungsten, platinum, erbium, lanthanum, niobium, or rhodium.

Example 53 comprises the apparatus of any one of examples 43-52, further comprising a field effect transistor, wherein a channel region of the field effect transistor comprises the second monolayer.

Example 54 comprises the apparatus of example 53, wherein the field effect transistor comprises a gate electrode region comprising the fourth layer.

Example 55 comprises the apparatus of example 54, wherein the field effect transistor is a nanoribbon field effect transistor.

Example 56 is a method comprising: forming a monolayer on a first substrate, the monolayer comprising a transition metal dichalcogenide or transition metal dichalcogenide alloy; forming a first layer on a surface of the monolayer; forming a second layer on a surface of a second substrate; bonding the first layer to the second layer; and separating the first substrate from the first layer.

Example 57 comprises the method of example 56, wherein bonding the first layer to the second layer comprises: forming a third layer on a surface of the first layer; forming a fourth layer on a surface of the second layer; and bonding the third layer to the fourth layer by diffusion bonding the third layer to the fourth layer to create a diffusion bonding layer, the diffusion bonding layer comprising the third layer and the fourth layer.

Example 58 comprises the method of example 57, wherein a thickness of the third layer is in a range of about 1-2 nanometers.

Example 59 comprises the method of example 57, wherein a thickness of the fourth layer is in a range of about 1-2 nanometers.

Example 60 comprises the method of example 57, wherein a thickness of the diffusion bonding layer is about 5 nanometers or less.

Example 61 comprises the method of example 57, wherein a thickness of the diffusion bonding layer is in a range of about 2-4 nanometers.

Example 62 comprises the method of example 56, wherein the surface of the monolayer is a first surface of the monolayer, the method further comprising forming a third layer on a second surface of the monolayer after bonding the first layer to the second layer, the second surface of the monolayer opposite the first surface of the monolayer, the third layer comprising oxygen.

Example 63 comprises the method of example 56, wherein the first layer comprises oxygen.

Example 64 comprises the method of any one of examples 56-63, wherein the first layer comprises an atomic composition of 0.1% or less of sulfur, selenium, or tellurium at an interface between the monolayer and the first layer.

Example 65 comprises the method of any one of examples 56-63, wherein the first layer does not comprise sulfur, selenium, or tellurium.

Example 66 comprises the method of any one of examples 56-65, wherein the second layer comprises: aluminum and oxygen; yttrium and oxygen; zirconium and oxygen; tungsten and oxygen; titanium and oxygen; zinc and oxygen; niobium and oxygen; or amorphous silicon.

Example 67 comprises the method of any of examples 56-65, wherein the second layer comprises gold, silver, titanium, or zirconium.

Example 68 comprises the method of any one of examples 56-65, wherein the second layer comprises: niobium and oxygen; tantalum and oxygen; and vanadium and oxygen.

Example 69 comprises the method of any one of examples 56-68, wherein the transition metal dichalcogenide comprises: a transition metal; and sulfur, selenium, or tellurium.

Example 70 comprises the method of example 69, wherein the transition metal is titanium, molybdenum, tungsten, platinum, erbium, lanthanum, niobium, or rhodium.

Example 71 comprises the method of any one of examples 56-68, wherein the transition metal dichalcogenide alloy comprises: a first transition metal and a second transition metal; and sulfur, selenium, or tellurium.

Example 72 comprises the method of example 71, wherein the first transition metal is titanium, molybdenum, tungsten, platinum, erbium, lanthanum, rhodium, or niobium; and the second transition metal is titanium, molybdenum, tungsten, platinum, erbium, lanthanum, rhodium, or niobium, the first transition metal different than the second transition metal.

1. An apparatus comprising:
a substrate;
a monolayer positioned above the substrate, the monolayer comprising a transition metal dichalcogenide or transition metal dichalcogenide alloy;
a first layer positioned adjacent to the monolayer and between the monolayer and the substrate; and
a second layer positioned adjacent to the substrate and between the first layer and the substrate.

2. The apparatus of claim 1, wherein the first layer comprises an atomic composition of about 0.1% or less of sulfur, selenium, or tellurium at an interface between the monolayer and the first layer.

3. The apparatus of claim 1, wherein the second layer comprises aluminum and oxygen;
yttrium and oxygen;
zirconium and oxygen;
tungsten and oxygen;
titanium and oxygen;
zinc and oxygen;
niobium and oxygen; or
amorphous silicon.

4. The apparatus of any of claim 1, wherein the second layer comprises:
gold;
silver;
titanium;
zirconium;
niobium and oxygen;
tantalum and oxygen; or
vanadium and oxygen.

5. The apparatus of claim 1, wherein the substrate comprises silicon.

6. The apparatus of claim 1, wherein the transition metal dichalcogenide comprises:
a transition metal; and
sulfur, selenium, or tellurium.

7. The apparatus of claim 6, wherein the transition metal is titanium, molybdenum, tungsten, platinum, erbium, lanthanum, niobium, or rhodium.

8. The apparatus of claim 1, wherein a thickness of the second layer is about 5 nanometers or less.

9. The apparatus of claim 1, wherein the monolayer is a first monolayer, the apparatus further comprising:
a second monolayer positioned above the first monolayer, the second monolayer comprising the transition metal dichalcogenide or transition metal dichalcogenide;
a third layer positioned adjacent to the second monolayer and between the first monolayer and the second monolayer; and
a fourth layer positioned adjacent to the third layer between the third layer and the first monolayer.

10. The apparatus of claim 1, further comprising a field effect transistor, wherein the first layer, the monolayer, and the field effect transistor are located in an integrated circuit die having a die edge, the first layer and the monolayer positioned laterally between the field effect transistor and the die edge.

11. The apparatus of any of claim 1, wherein the apparatus is an integrated circuit component comprising the monolayer, the first layer, the second layer, and the substrate.

12. The apparatus of claim 11, wherein the integrated circuit component is attached to a printed circuit board.

13. An apparatus comprising:
a substrate comprising silicon;
a first monolayer positioned above the substrate comprising a transition metal dichalcogenide or transition metal dichalcogenide, wherein the transition metal dichalcogenide comprises sulfur, selenium, or tellurium;
a first layer positioned adjacent to the first monolayer and between the first monolayer and the substrate;
a second layer positioned adjacent to the substrate and between the first layer and the substrate;
a second monolayer positioned above the substrate, the second monolayer substantially coplanar with the first monolayer, the second monolayer comprising the transition metal dichalcogenide or transition metal dichalcogenide;
a third layer positioned adjacent to the second monolayer and between the second monolayer and the substrate; and
a fourth layer positioned adjacent to the substrate and between the third layer and the fourth layer, the fourth layer comprising a metal.

14. The apparatus of claim 13, wherein the first layer comprises an atomic composition of about 0.1% or less of sulfur, selenium, or tellurium at an interface between the first monolayer and the first layer.

15. The apparatus of claim 13, wherein the second layer comprises:
aluminum and oxygen;
yttrium and oxygen;
zirconium and oxygen;
tungsten and oxygen;
titanium and oxygen;
zinc and oxygen;
niobium and oxygen; or
amorphous silicon.

16. The apparatus of claim 13, further comprising a field effect transistor, wherein a channel region of the field effect transistor comprises the second monolayer.

17. A method comprising:
forming a monolayer on a first substrate, the monolayer comprising a transition metal dichalcogenide or transition metal dichalcogenide alloy;
forming a first layer on a surface of the monolayer;
forming a second layer on a surface of a second substrate;
bonding the first layer to the second layer; and
separating the first substrate from the first layer.

18. The method of claim 17, wherein bonding the first layer to the second layer comprises:
forming a third layer on a surface of the first layer;
forming a fourth layer on a surface of the second layer; and
bonding the third layer to the fourth layer by diffusion bonding the third layer to the fourth layer to create a diffusion bonding layer, the diffusion bonding layer comprising the third layer and the fourth layer.

19. The method of claim 17, wherein the second layer comprises:
aluminum and oxygen;
yttrium and oxygen;
zirconium and oxygen;
tungsten and oxygen;
titanium and oxygen;
zinc and oxygen;
niobium and oxygen;
amorphous silicon;
gold;
silver;
titanium, or
zirconium.

20. The method of any claim 17, wherein the transition metal dichalcogenide comprises:
a transition metal, wherein the transition metal is titanium, molybdenum, tungsten, platinum, erbium, lanthanum, niobium, or rhodium; and
sulfur, selenium, or tellurium.
